(19) United States
(12) Patent Application Publication
(10) Pub. No.: US 2023/0135728 A1
(43) Pub. Date: May 4, 2023

(54) HIGH-FREQUENCY CIRCUIT MODULE

(71) Applicant: Sumitomo Electric Industries, Ltd., Osaka-shi, Osaka (JP)

(72) Inventors: Mikoto NAKAMURA, Osaka-shi (JP); Yusuke YAHATA, Osaka-shi (JP)

(73) Assignee: Sumitomo Electric Industries, Ltd., Osaka-shi, Osaka (JP)

(21) Appl. No.: 17/918,382

(22) PCT Filed: Apr. 30, 2021
(86) PCT No.: PCT/JP2021/017207

§ 371 Date: Oct. 12, 2022

(30) Foreign Application Priority Data
May 14, 2020 (JP) 2020-085423

(51) Int. Cl. H05K 1/02

(52) U.S. Cl. CPC H05K 1/0251

(57) ABSTRACT

A high frequency circuit module mounted on a first board that is a printed circuit board, includes: a second board; a high frequency circuit disposed on a first surface of the second board; a high frequency signal line disposed on the first surface of the second board, and extending from the high frequency circuit; and a matching member disposed on the first surface so as to cover at least a part of the high frequency signal line, and configured to adjust an impedance in the high frequency signal line. The matching member includes: a reference potential conductor separated from the high frequency signal line in a direction from a second surface, of the second board, opposite to the first surface, toward the first surface, the reference potential conductor being set at a reference potential; and a dielectric disposed between the reference potential conductor and the high frequency signal line.

### TECHNICAL FIELD

The present disclosure relates to a high frequency circuit module. This application claims priority on Japanese Patent Application No. 2020-085423 filed on May 14, 2020, the entire content of which is incorporated herein by reference.

### BACKGROUND ART

When a device such as a high frequency circuit module is mounted on a printed circuit board, impedance matching is required at a connection portion between a terminal of the device and a circuit on the printed circuit board. PATENT LITERATURE 1 discloses a printed circuit board having a microstrip line structure, in which a part of a trace layer (ground) directly below a pad at a surface layer connected to a terminal of a device is removed to adjust an impedance.

### CITATION LIST

### Patent Literature

PATENT LITERATURE 1: Japanese Laid-Open Patent Publication No. 2009-140993

### SUMMARY OF THE INVENTION

A high frequency circuit module according to one aspect of the present disclosure is mounted on a first board as a printed circuit board, and includes: a second board; a high frequency circuit disposed on a first surface of the second board; a high frequency signal line disposed on the first surface of the second board, and extending from the high frequency circuit; and a matching member disposed on the first surface so as to cover at least a part of the high frequency signal line, and configured to adjust an impedance in the high frequency signal line. The matching member includes: a reference potential conductor separated from the high frequency signal line in a direction from a second surface, of the second board, opposite to the first surface, toward the first surface, the reference potential conductor being set at a reference potential; and a dielectric disposed between the reference potential conductor and the high frequency signal line.

The present disclosure can be realized not only as a high frequency circuit module having such a characteristic configuration as described above, but also as a communication device including the high frequency circuit module.

### BRIEF DESCRIPTION OF DRAWINGS

FIG. 1 shows an example of a configuration of a high frequency circuit module according to an embodiment.

FIG. 2 is a cross-sectional view taken along an A-A line in FIG. 1.

FIG. 3 is a side sectional view showing a manner of mounting a matching member on a board according to the embodiment.

FIG. 4 is a block diagram showing an example of a configuration of a high frequency circuit according to the embodiment.

FIG. 5 is a plan view showing an example of a state where the high frequency circuit module according to the embodiment is mounted on a printed circuit board.

FIG. 6 is a side sectional view showing an example of a state where the high frequency circuit module according to the embodiment is mounted on a printed circuit board.

FIG. 7 is a side sectional view showing one modification of the configuration of the high frequency circuit module according to the embodiment.

### DETAILED DESCRIPTION

<Problems to be Solved by the Present Disclosure>

For example, as a result of a design change in the printed circuit board, impedance mismatching may occur at the connection portion between the terminal of the device and the circuit on the printed circuit board. A device capable of easily adjusting the impedance in accordance with such a design change in the printed circuit board, has been desired.

<Effects of the Present Disclosure>

According to the present disclosure, impedance matching is achieved at a connection portion between a terminal of a high frequency circuit module and a circuit on a printed circuit board, in accordance with a design change in the printed circuit board.

<Outline of Embodiment of the Present Disclosure>

Hereinafter, the outline of an embodiment of the present disclosure is listed and described.

(1) A high frequency circuit module according to the present embodiment is mounted on a first board as a printed circuit board, and includes: a second board; a high frequency circuit disposed on a first surface of the second board; a high frequency signal line disposed on the first surface of the second board, and extending from the high frequency circuit; and a matching member disposed on the first surface so as to cover at least a part of the high frequency signal line, and configured to adjust an impedance in the high frequency signal line. The matching member includes: a reference potential conductor separated from the high frequency signal line in a direction from a second surface, of the second board, opposite to the first surface, toward the first surface, the reference potential conductor being set at a reference potential; and a dielectric disposed between the reference potential conductor and the high frequency signal line. Thus, the matching member is configured in accordance with the configuration of the first board, whereby impedance matching can be achieved at the connection portion between the terminal of the high frequency circuit module and the wiring on the first board.

(2) The high frequency circuit module according to the present embodiment may further include a ground terminal disposed on the second surface of the second board, and a via penetrating the second board at the ground terminal, and the reference potential conductor may be conductive to the ground terminal through the via. Thus, the potential in the reference potential conductor can be set to a ground potential in the first board.

(3) In the high frequency circuit module according to the present embodiment, a pair of the ground terminals may be disposed on the second surface, a pair of the vias may penetrate the second board at the pair of the ground terminals, respectively, and opposed ends of the reference potential conductor may be connected to the pair of the vias, respectively. Thus, the matching member lies across the high frequency signal line like a bridge, whereby the matching member can be stably mounted to the second board.

(4) In the high frequency circuit module according to the present embodiment, the matching member may be constituted by a third board including a conductor foil and an insulating base material, the reference potential conductor may be formed of the conductor foil, and the dielectric may be formed of the insulating base material. Thus, the matching member can be easily constituted by the third board as a printed circuit board.

(5) In the high frequency circuit module according to the present embodiment, the reference potential conductor may be conductive to a ground terminal disposed on the second board, through a second via penetrating the third board. Thus, the reference potential conductor can be connected to the ground terminal by a simple configuration.

(6) In the high frequency circuit module according to the present embodiment, the impedance in the high frequency signal line may be adjusted by at least one of a width of the conductor foil and a thickness of the insulating base material. Thus, the impedance in the high frequency signal line can be easily adjusted.

<Details of Embodiment of the Present Disclosure>

Hereinafter, details of the embodiment of the present invention will be described with reference to the drawings. At least some parts of the embodiment described below may be combined together as desired.

[1. High Frequency Circuit Module]

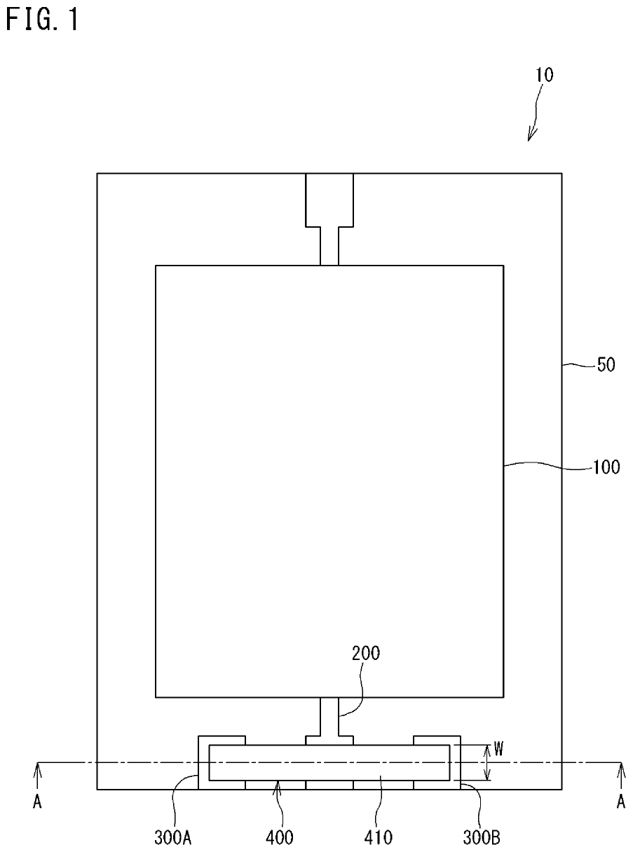

FIG. 1 shows an example of a configuration of a high frequency circuit module according to the present embodiment.

The high frequency circuit module 10 includes a board (second board) 50, an RF (Radio Frequency) circuit 100, an RF signal line 200, GND (ground) conductors 300A, 300B, and a matching member 400.

The board 50 is, for example, a double-faced printed circuit board. A printed circuit formed of a conductor foil is disposed on each of a front surface (first surface) and a rear surface (second surface) of the printed circuit board.

The RF circuit 100 is disposed on the front surface of the board 50. The RF circuit 100 is an example of a high frequency circuit, and outputs an RF signal (high frequency signal).

The RF signal line 200 is disposed on the front surface of the board 50. The RF signal line 200 extends from the RF circuit 100, and transmits the RF signal outputted from the RF circuit 100. The RF signal line 200 is formed of a conductor foil.

The GND conductors 300A, 300B are disposed on the surface of the board 50 so as to sandwich the RF signal line 200. The GND conductors 300A, 300B are formed of a conductor foil.

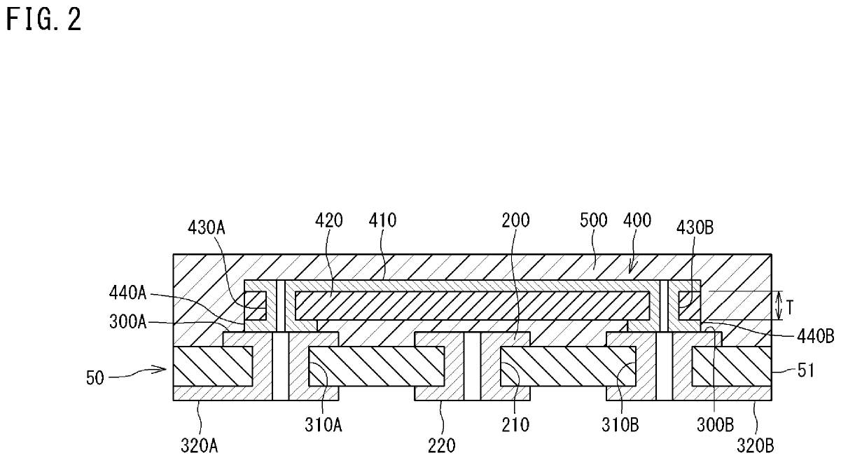

FIG. 2 is a cross-sectional view taken along an A-A line in FIG. 1. The board 50 includes an insulating base material 51, and a conductor foil that forms a microstrip line, for example. In FIG. 2, the thickness of the conductor foil is shown larger than its actual thickness.

As shown in FIG. 2, at an end portion of the RF signal line 200, a through-hole 210 penetrating the board 50 is provided. Furthermore, at the GND conductors 300A, 300B, a pair of through-holes (vias) 310A, 310B penetrating the board 50 are provided. The inner peripheries of the through-holes 210, 310A, and 310B are plated with copper or the like.

On the rear surface (second surface) of the board 50, an output terminal 220 is disposed. The output terminal 220 is formed of a conductor foil. The output terminal 220 is positioned directly below the end portion of the RF signal line 200, and the RF signal line 200 and the output terminal 220 are conductive to each other through the through-hole 210.

On the rear surface of the board 50, a pair of GND terminals 320A, 320B are disposed so as to sandwich the output terminal 220. Each of the GND terminals 320A, 320B is formed of a conductor foil. The GND terminal 320A is positioned directly below the GND conductor 300A, and the GND terminal 320B is positioned directly below the GND conductor 300B. The GND terminal 320A and the GND conductor 300A are conductive to each other through the through-hole 310A, and the GND terminal 320B and the GND conductor 300B are conductive to each other through the through-hole 310B.

The matching member 400 is disposed on the front surface of the board 50. The matching member 400 includes a reference potential conductor 410 and a dielectric 420. The reference potential conductor 410 is separated from the RF signal line 200 in a height direction of the board 50, e.g., in a direction from the rear surface toward the front surface of the board 50. The reference potential conductor 410 has a plate shape or a foil shape. The reference potential conductor 410 is disposed in parallel to the RF signal line 200 in the height direction so as to be positioned directly above the RF signal line 200. In a specific example, the reference potential conductor 410 is positioned directly above the end portion of the RF signal line 200.

The dielectric 420 is disposed between the reference potential conductor 410 and the RF signal line 200. In a specific example, the reference potential conductor 410 is mounted to a front surface of the dielectric 420. That is, the reference potential conductor 410 and the dielectric 420 are disposed in a layered state. The dielectric 420 has the same shape as the reference potential conductor 410 in a plan view. In a specific example, the reference potential conductor 410 and the dielectric 420 have congruent rectangular shapes in a plan view.

A pair of connection conductors 440A, 440B are disposed on a rear surface of the dielectric 420. The connection conductors 440A, 440B are disposed at opposed ends of the dielectric 420. Each of the connection conductors 440A, 440B is formed of a conductor foil.

For example, the matching member 400 is constituted by a printed circuit board (third board). The reference potential conductor 410 is a conductor foil of the printed circuit board, for example. The dielectric 420 is an insulating base material of the printed circuit board, for example. The matching member 400 has a pair of through-holes (second vias) 430A, 430B at opposed end portions of the reference potential conductor 410. The inner peripheries of the through-holes 430A, 430B are plated with copper or the like. The connection conductors 440A, 440B are positioned directly below the opposed ends of the reference potential conductor 410, respectively. One end of the reference potential conductor 410 and the connection conductor 440A are conductive to each other through the through-hole 430A, and the other end of the reference potential conductor 410 and the connection conductor 440B are conductive to each other through the through-hole 430B.

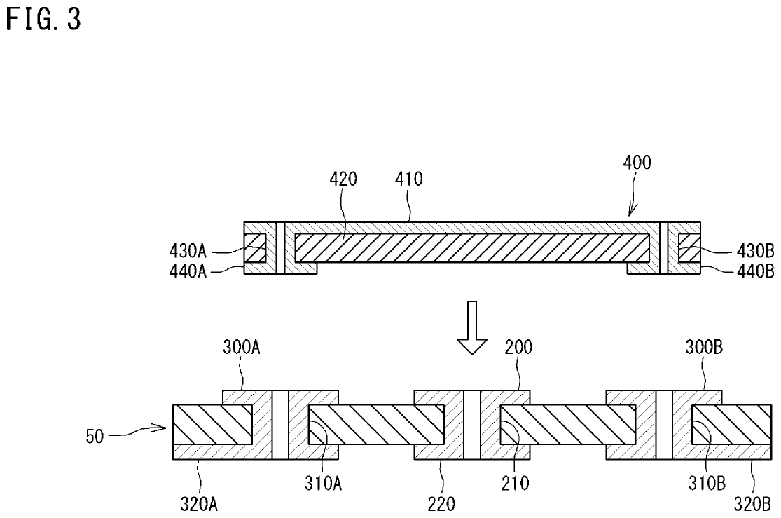

FIG. 3 is a side sectional view showing a manner of mounting the matching member 400 on the board 50 according to the present embodiment. The matching member 400 is mounted on the board 50 formed as a separate component. The distance between the connection conductor 440A and the connection conductor 440B is substantially equal to the distance between the GND conductor 300A and the GND conductor 300B. The connection conductors 440A, 440B are positioned with respect to the GND conductors 300A, 300B, respectively. That is, the connection conductor 440A is connected to the GND conductor 300A, and the connection conductor 440B is connected to the GND conductor 300B. Thus, the reference potential conductor 410 is conductive to the GND terminals 320A, 320B.

FIG. 2 is referred to again. On the front surface of the board 50 having the matching member 400 mounted thereto, a liquid synthetic resin is laminated and then solidified, thereby forming a mold resin 500. The mold resin 500 seals the RF circuit 100, the RF signal line 200, the GND conductors 300A, 300B, and the matching member 400.

[2. Example of High Frequency Circuit]

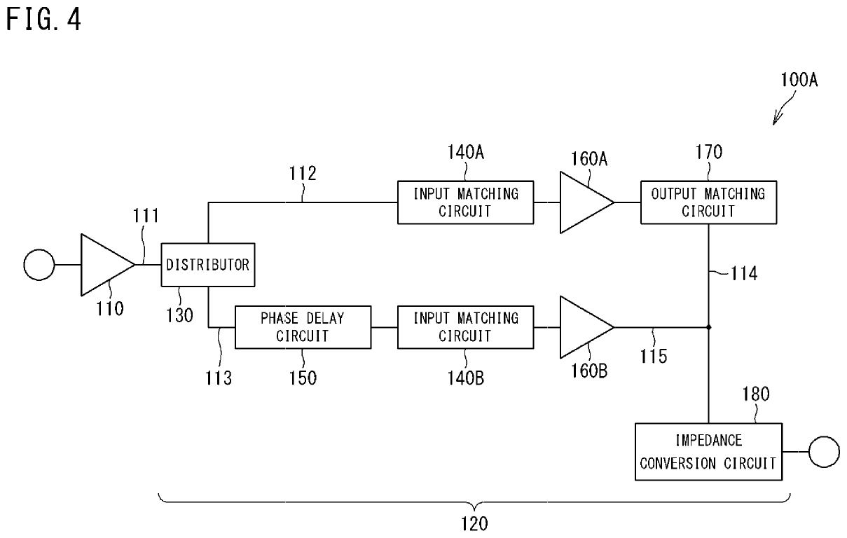

FIG. 4 is a block diagram showing an example of a configuration of a high frequency circuit according to the present embodiment. An amplification circuit 100A shown in FIG. 4 is a circuit for amplifying a radio communication signal, and is an example of a high frequency circuit 100. The amplification circuit 100A includes a driver amplifier 110 and a Doherty amplification circuit 120. The Doherty amplification circuit 120 includes a distributor 130, input matching circuits 140A, 140B, a phase delay circuit 150, a carrier amplifier 160A, an output matching circuit 170, a peak amplifier 160B, and an impedance conversion circuit 180.

The driver amplifier 110, the carrier amplifier 160A, and the peak amplifier 160B are constituted by transistor chips such as a MOSFET (Metal-Oxide-Semiconductor Field-Effect Transistor), an IGBT (Insulated Gate Bipolar Transistor), a GaN HEMT (Gallium Nitride High-Electron-Mobility Transistor), and the like. The driver amplifier 110, the carrier amplifier 160A, and the peak amplifier 160B may be constituted by transistor chips having the same structure, material, and characteristics, or may be constituted by transistor chips different in at least one of the structure, material, and characteristics.

In the amplification circuit 100A, the driver amplifier 110 is a preamplifier, and an input side of the Doherty amplification circuit 120 is connected to an output terminal (drain terminal) of the driver amplifier 110. More specifically, a signal line 111 extending from the output terminal of the driver amplifier 110 is connected to the input side of the Doherty amplification circuit 120.

The Doherty amplification circuit 120 includes the distributor 130. The aforementioned signal line 111 is connected to an input terminal of the distributor 130. Signal lines 112, 113 extend from two output terminals of the distributor 130, respectively. The driver amplifier 110 amplifies an inputted high frequency signal, and outputs the amplified signal. The distributor 130 distributes the high frequency signal outputted from the driver amplifier 110 to the signal lines 112, 113.

The signal line 112 is connected to an input terminal (gate terminal) of the carrier amplifier 160A through the input matching circuit 140A. The carrier amplifier 160A is biased at class A or AB, amplifies an input signal regardless of the power level of the input signal, and outputs the amplified signal (first amplified signal).

The signal line 113 is connected to an input terminal (gate terminal) of the peak amplifier 160B through the phase delay circuit 150 and the input matching circuit 140B. The phase delay circuit 150 gives a phase delay of 90° to the input signal. The peak amplifier 160B is biased at class C, amplifies an input signal when the power level of the input signal is not lower than a predetermined value, and outputs the amplified signal (second amplified signal).

An output terminal (drain terminal) of the carrier amplifier 160A is connected to the output matching circuit 170. An output signal line 114 extends from the output matching circuit 170. The output matching circuit 170 gives a phase delay of 90° to the input signal. The output matching circuit 170 is an impedance conversion circuit, and adjusts a load impedance of the carrier amplifier 160A. The output signal line 114 transmits the first amplified signal outputted from the carrier amplifier 160A.

An output signal line 115 extends from the output terminal (drain terminal) of the peak amplifier 160B. The output signal line 115 transmits the second amplified signal outputted from the peak amplifier 160B. The output signal line 114 and the output signal line 115 are coupled with each other and connected to the impedance conversion circuit 180.

A synthetic signal of the amplified signal (first amplified signal) outputted from the peak amplifier 160B and the amplified signal (second amplified signal) outputted from the carrier amplifier 160A, is inputted to the impedance conversion circuit 180. The impedance conversion circuit 180 adjusts the impedance in the entire Doherty amplification circuit 120.

When the power level of the input signal from the driver amplifier 110 is low, the Doherty amplification circuit 120 having the above configuration amplifies the signal by the carrier amplifier 160A, and outputs the amplified signal. Meanwhile, when the power level of the input signal from the driver amplifier 110 is high, the Doherty amplification circuit 120 amplifies the signal by each of the carrier amplifier 160A and the peak amplifier 160B, synthesizes the two amplified signals, and outputs a synthetic signal. The output side of the impedance conversion circuit 180 is connected to the RF signal line 200. The RF signal line 200 transmits an output signal, of the amplification circuit 100A, which is a high frequency signal.

[3. Example of Mounting of High Frequency Circuit Module]

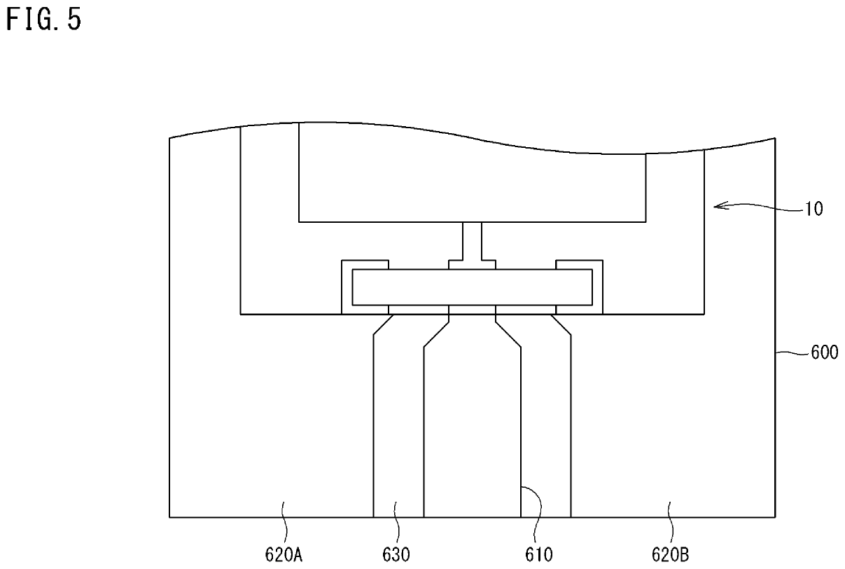

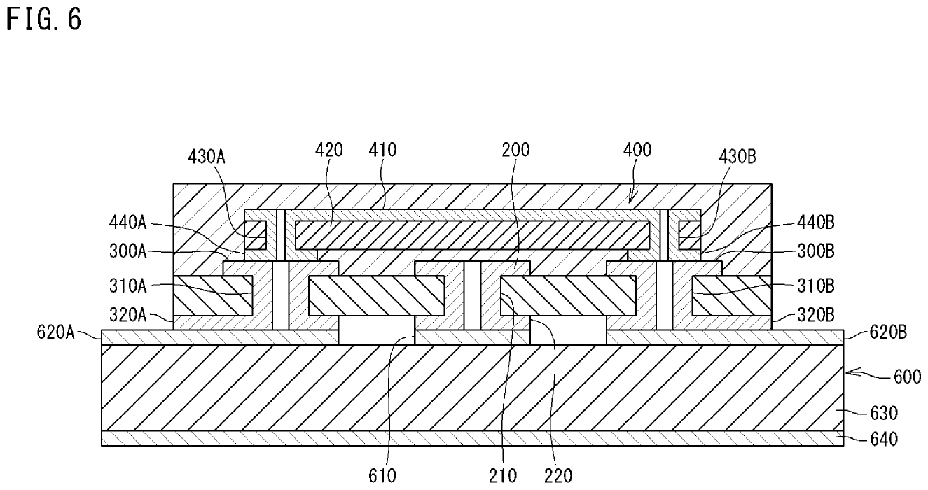

The high frequency circuit module 10 is mounted on a main board (first board). FIG. 5 is a plan view showing an example of a state where the high frequency circuit module according to the present embodiment is mounted on a printed circuit board. FIG. 6 is a side sectional view thereof. On a main board 600, for example, a transmission circuit for radio communication, a signal processing circuit, etc., are mounted in addition to the high frequency circuit module 10. The main board (first board) 600 is, for example, a double-faced printed circuit board having a microstrip structure. A printed circuit formed of a conductor foil is formed on each of a front surface and a rear surface of the main board 600.

The main board 600 includes an insulating base material 630, and a conductor foil that forms a microstrip line, for example. In FIG. 6, the thickness of the conductor foil is shown larger than its actual thickness.

On the front surface of the main board 600, a signal line 610 and GND conductors 620A, 620B are disposed. Each of the signal line 610 and the GND conductors 620A, 620B is formed of a conductor foil.

An end portion of the signal line 610 is a terminal, and the terminal is connected to an output terminal 220 of the high frequency circuit module 10.

Each of the GND conductors 620A, 620B is set at a ground potential. The GND conductor 620A is connected to the GND terminal 320A of the high frequency circuit module 10, and the GND conductor 620B is connected to the GND terminal 320B of the high frequency circuit module 10. Thus, the reference potential conductor 410 and the GND conductors 620A, 620B are conductive to one another, and the reference potential conductor 410 is set at the ground potential. Furthermore, on the rear surface of the main board 600, a ground plane 640 formed of a conductor foil is disposed.

[4. Impedance Adjustment by Matching Member]

A characteristic impedance in a microstrip line is expressed by the following formula.

$${Z}_{0} = \frac{60}{\sqrt{0.475 {ε}_{r} + 0.67}} ln [ \frac{4 h}{0.67 ( 0.8 W + t )} ] \qquad [ Math . 1 ]$$

where w indicates the line width, h indicates the height of the insulating base material 630, and t indicates the thickness (height) of the conductor foil. Therefore, the characteristic impedance in the signal line 610 can be obtained by the above formula.

The impedance at the output terminal 220 is required to be matched to the impedance in the signal line 610. In the high frequency circuit module 10 according to the present embodiment, the impedance at the output terminal 220 is easily adjusted by the matching member 400.

As shown in FIG. 2, the dielectric 420 is disposed between the RF signal line 200 and the reference potential conductor 410. Therefore, the RF signal line 200, the reference potential conductor 410, and the dielectric 420 form a capacitor. In FIG. 2, since the thickness of the conductor foil is shown larger than its actual thickness, a gap is present between the dielectric 420 and the RF signal line 200. However, since the actual thickness of the conductor foil is several tens of micrometers at most, the dielectric 420 is in contact with the RF signal line 200. Even if the dielectric 420 and the RF signal line 200 are separated from each other, the distance between them is several tens of micrometers. Moreover, even when an air layer or another insulator (synthetic resin or the like) is present between the dielectric 420 and the RF signal line 200, insulation between the RF signal line 200 and the reference potential conductor 410 is maintained, so that the function as the capacitor is similarly achieved.

By the capacitance of the capacitor, the impedance in the RF signal line 200, i.e., the impedance at the output terminal 220, is determined.

The capacitance of a plate capacitor is proportional to a distance between opposing electrodes (i.e., a thickness of a dielectric) and an area of the opposing electrodes. Therefore, in the high frequency circuit module 10 according to the present embodiment, the capacitance is determined based on a width W of the reference potential conductor 410 (see FIG. 1) and a thickness (height) T of the dielectric 420 (see FIG. 2), and as a result, the impedance at the output terminal 220 is determined. Therefore, the impedance at the output terminal 220 can be easily adjusted by adjusting the width W of the reference potential conductor 410 and the thickness T of the dielectric 420.

[5. Modifications]

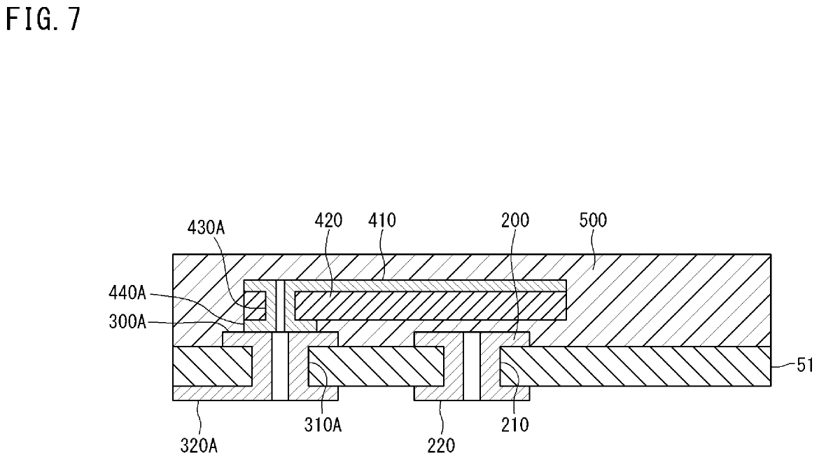

In the above embodiment, the through-holes 430A, 430B are disposed at the opposed ends of the reference potential conductor 410, and the connection conductors 440A, 440B respectively disposed below the through-holes 430A, 430B are respectively connected to the pair of GND conductors 300A, 300B. However, the present disclosure is not limited to this configuration. FIG. 7 is a side sectional view showing one modification of the configuration of the high frequency circuit module according to the present embodiment. In FIG. 7, the through-hole 430A is disposed at one end of the reference potential conductor 410, and the connection conductor 440A disposed below the through-hole 430A is connected to one GND conductor 300A. In this modification, as well, the reference potential conductor 410 is disposed so as to cover the RF signal line 200, and the dielectric 420 is disposed between the reference potential conductor 410 and the RF signal line 200. Therefore, also in this configuration, the impedance at the output terminal 220 can be adjusted.

In the above embodiment, the reference potential conductor 410 is conductive to the GND terminals 320A, 320B disposed on the board 50, whereby the potential of the reference potential conductor 410 is set to the ground potential in the main board 600. The potential of the reference potential conductor 410 may be any potential as long as it is a fixed potential. For example, the reference potential may be a ground potential of an RF signal outputted from the RF circuit 100, i.e., a DC power supply potential in the RF circuit 100.

In the above embodiment, the board 50 is a double-faced printed circuit board. However, the present disclosure is not limited thereto. For example, the board 50 may be a multilayer printed circuit board. In this case, the output terminal 220 may not necessarily be disposed on the rear surface of the board 50, and may be disposed inside the board 50. The RF signal line 200 and the output terminal 220 may be conductive to each other not through the through-hole 210 but through an inner via. Moreover, the GND terminals 320A, 320B may not necessarily be disposed on the rear surface of the board 50, and may be disposed inside the board 50. The GND conductors 300A, 300B may be conductive to the GND terminals 320A, 320B not through the through-holes 310A, 310B but through inner vias, respectively.

[6. Effects]

As described above, the high frequency circuit module 10 is mounted on the main board 600 which is a printed circuit board. The high frequency circuit module 10 includes the board 50, the RF circuit 100, the RF signal line 200, and the matching member 400. The RF circuit 100 is disposed on the front surface of the board 50. The RF signal line 200 is disposed on the front surface of the board 50, and extends from the RF circuit 100. The matching member 400 is disposed on the front surface of the board 50 so as to cover at least a part of the RF signal line 200. The matching member 400 adjusts the impedance in the RF signal line 200. The matching member 400 includes the reference potential conductor 410 and the dielectric 420. The reference potential conductor 410 is separated from the RF signal line in the direction from the rear surface toward the front surface of the board 50, and is set at the reference potential. The dielectric 420 is disposed between the reference potential conductor 410 and the RF signal line 200. Thus, the matching member is configured in accordance with the configuration of the first board, whereby impedance matching can be achieved at the connection portion between the terminal of the high frequency circuit module and the circuit on the first board.

The high frequency circuit module 10 may further include the GND terminals 320A, 320B and the through-holes 310A, 310B. The GND terminals 320A, 320B are disposed on the rear surface of the board 50. The through-holes 310A, 310B penetrate the board 50 at the GND terminals 320A, 320B. The reference potential conductor 410 may be conductive to the GND terminals 320A, 320B through the through-holes 310A, 310B. Thus, the potential in the reference potential conductor 410 can be set to the GND potential in the main board 600.

The pair of GND terminals 320A, 320B may be disposed on the rear surface of the board 50. The through-holes 310A, 310B may penetrate the board 50 at the pair of GND terminals 320A, 320B, respectively. The opposed ends of the reference potential conductor 410 may be connected to the pair of through-holes 310A, 310B, respectively. Thus, the matching member 400 lies across the RF signal line 200 like a bridge, whereby the matching member 400 can be stably mounted to the board 50.

The matching member 400 may be constituted by a printed circuit board including a conductor foil and an insulating base material. The reference potential conductor 410 may be formed of the conductor foil. The dielectric 420 may be formed of the insulating base material. Thus, the matching member 400 can be easily constituted by the printed circuit board.

The reference potential conductor 410 may be conductive to the GND terminals 320A, 320B disposed on the board 50 through the through-holes 430A, 430B penetrating the printed circuit board. Thus, the reference potential conductor 410 can be connected to the GND terminals 320A, 320B by a simple structure.

The impedance in the RF signal line 200 may be adjusted by at least one of the width of the conductor foil forming the reference potential conductor 410 and the thickness of the insulating base material forming the dielectric 420. Thus, the impedance in the RF signal line 200 can be easily adjusted.

[7. Supplementary Note]

The embodiment disclosed herein is merely illustrative in all aspects and is not restrictive. The scope of the present disclosure is defined by the scope of the claims rather than the embodiment described above, and is intended to include meaning equivalent to the scope of the claims and all modifications within the scope.

### REFERENCE SIGNS LIST

10 high frequency circuit module

50 board (second board)

51 insulating base material

100 RF circuit (high frequency circuit)

100A amplification circuit

110 driver amplifier

111 to 115 signal line

120 Doherty amplification circuit

130 distributor

140A, 140B input matching circuit

150 phase delay circuit

160A carrier amplifier

160B peak amplifier

170 output matching circuit

180 impedance conversion circuit

200 RF signal line (radio frequency signal line)

210 through-hole

430A, 430B through-hole

220 output terminal

300A, 300B GND conductor

310A, 310B through-hole (via)

320A, 320B GND terminal (ground terminal)

400 matching member

410 reference potential conductor

420 dielectric

440A, 440B connection conductor

430A, 430B through-hole (second via)

500 mold resin

600 main board (first board)

610 signal line

630 insulating base material

620A, 620B GND conductor

640 ground plane

1. A high frequency circuit module mounted on a first board that is a printed circuit board, comprising:
a second board;
a high frequency circuit disposed on a first surface of the second board;
a high frequency signal line disposed on the first surface of the second board, and extending from the high frequency circuit; and
a matching member disposed on the first surface so as to cover at least a part of the high frequency signal line, and configured to adjust an impedance in the high frequency signal line, wherein
the matching member includes
a reference potential conductor separated from the high frequency signal line in a direction from a second surface, of the second board, opposite to the first surface, toward the first surface, the reference potential conductor being set at a reference potential, and
a dielectric disposed between the reference potential conductor and the high frequency signal line.

2. The high frequency circuit module according to claim 1, further comprising:
a ground terminal disposed on the second surface of the second board; and
a via penetrating the second board at the ground terminal, wherein the reference potential conductor is conductive to the ground terminal through the via.

3. The high frequency circuit module according to claim 2, wherein
a pair of the ground terminals are disposed on the second surface,
a pair of the vias penetrate the second board at the pair of the ground terminals, respectively, and
opposed ends of the reference potential conductor are connected to the pair of the vias, respectively.

4. The high frequency circuit module according to claim 1, wherein
the matching member is constituted by a third board including a conductor foil and an insulating base material,
the reference potential conductor is formed of the conductor foil, and
the dielectric is formed of the insulating base material.

5. The high frequency circuit module according to claim 4, wherein
the reference potential conductor is conductive to a ground terminal disposed on the second board, through a second via penetrating the third board.

6. The high frequency circuit module according to claim 4, wherein
the impedance in the high frequency signal line is adjusted by at least one of a width of the conductor foil and a thickness of the insulating base material.
